(19) United States
(12) Patent Application Publication
(10) Pub. No.: US 2008/0040567 A1
(43) Pub. Date: Feb. 14, 2008

(54) Command control circuit

(75) Inventors: Koji Kuroki, Tokyo (JP); Shuichi Kubouchi, Tokyo (JP); Hiroki Fujisawa, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/882,425

(22) Filed: Aug. 1, 2007

(30) Foreign Application Priority Data
Aug. 9, 2006 (JP) 2006-217011

(51) Int. Cl. G11C 7/22; G06F 12/00

(52) U.S. Cl. 711/167; 365/189.011; 365/233.11

(57) ABSTRACT

A command control circuit includes a read-clock generation circuit that generates a read clock ICLK-R at the time of reading, a write-clock generation circuit that generates a write clock ICLK-W at the time of writing, and a burst chop AL counter that counts an additive latency of a burst chop command. The burst chop AL counter counts the burst chop command in synchronization with both the read clock ICLK-R and the write clock ICLK-W. This eliminates a need of separately arranging an AL counter that counts the burst chop command at the time of reading and an AL counter that counts the burst chop command at the time of writing.

### TECHNICAL FIELD

The present invention relates to a command control circuit. More specifically, the present invention relates to a command control circuit of a semiconductor memory device having a burst chop function.

### BACKGROUND OF THE INVENTION

In DRAMs (Dynamic Random Access Memory) of recent years, a synchronous DRAM that operates in synchronization with a clock has become mainly used. A speed of the clock used for the synchronous DRAM becomes faster year by year. However, in a DRAM core, a precharge operation, a sense operation, and the like are needed, and thus, it is not possible to increase the speed in proportion to a clock frequency. Accordingly, in the synchronous DRAM, a “prefetch circuit” is arranged between the DRAM core and input/output pins to perform a parallel-serial conversion in the prefetch circuit. Thereby, an apparent high-speed operation is achieved (see Japanese Patent Application Laid-open Nos. 2004-164769, 2004-310989, 2004-133961, 2003-272382, and 2004-310918).

For example, in a DDR2 synchronous DRAM, a 4-bit prefetch is performed in the prefetch circuit, and in a DDR3 synchronous DRAM, an 8-bit prefetch is performed in the prefetch circuit. Thereby, a high data transfer rate is achieved externally.

More specifically, in the DDR3 synchronous DRAM, 8-bit data is once read from the DRAM core at the time of reading, and after the 8-bit data is temporarily stored in the prefetch circuit, the data is burst-outputted to outside. On the contrary, at the time of writing, the 8-bit data burst-inputted from outside is temporarily stored in the prefetch circuit, and thereafter, the 8-bit data is written into the DRAM core at once. To perform such operations, in the synchronous DRAM, a prefetch number is basically defined as a minimum burst length.

However, to realize a faster data transfer rate, it is inevitably necessary to increase the prefetch number. Thus, when the prefetch number is defined as the minimum burst length, it becomes impossible to be compatible with a conventional synchronous DRAM. In the example of the DDR3 synchronous DRAM, when the minimum burst length is set to 8, an operation of burst length=4 which is possible in the DDR2 synchronous DRAM cannot be performed. As a result, the compatibility is lost.

To solve such a problem, a “burst chop function” has been proposed. The burst chop function is to make a designation in advance so that a burst operation stops in the middle at the time of issuing a read command or a write command. Accordingly, when it is assumed that the bust chop function is performed in the DDR3 synchronous DRAM, by the designation at the time of issuing the read command and the write command, it becomes possible to use a bust length=8 as a burst length=4. Thereby, even when the prefetch number increases, it becomes possible to be compatible with the past product (DDR2).

However, when the burst chop function is installed in a semiconductor memory device, there occurs a problem in that a configuration of a command control circuit becomes very complicated. That is, the command control circuit already includes a read AL counter that counts an additive latency of the read command, a CL counter that counts a CAS latency of the read command, a write AL counter that counts an additive latency of the write command, and a CWL counter that counts a CAS write latency of the write command, for example. Thus, when the burst chop function is added to this configuration, one more set of all of these counters is necessary. As a result, a circuit scale is nearly doubled.

### SUMMARY OF THE INVENTION

The present invention has been achieved in view of such problems, and an object thereof is to downsize a command control circuit of a semiconductor memory device having a burst chop function.

The above and other objects of the present invention can be accomplished by a command control circuit comprising:

a read-clock generation circuit that generates a read clock during a read operation;

a write-clock generation circuit that generates a write clock during a write operation; and

a burst chop AL counter that counts an additive latency of a burst chop command in synchronization with both the read clock and the write clock.

A method of issuing a burst chop command is not particularly limited. However, the burst chop command is preferably generated by a predetermined signal combination including a signal supplied via a predetermined address terminal.

According to the present invention, a burst chop AL counter operates in synchronization with both a read clock and a write clock. This eliminates a need of separately arranging an AL counter that counts the burst chop command at the time of reading and an AL counter that counts the burst chop command at the time of writing. As a result, it becomes possible to inhibit an increase in circuit scale of a command control circuit.

The burst chop AL counter is used commonly for write and read. Thus, it becomes possible to eliminate the need of separating the burst chop command into read-use and write-use at the previous stage of the burst chop AL counter. This makes it also possible to sufficiently maintain a latch margin in the command latch circuit.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a circuit diagram of a command control circuit according to a first embodiment of the present invention;

FIG. 2 is a block diagram of a semiconductor memory device employing the command control circuit shown in FIG. 1;

FIG. 3 is a timing chart showing a normal read operation;

FIG. 4 is a timing chart showing a read operation when the burst chop is performed;

FIG. 5 is a timing chart showing a normal write operation;

FIG. 6 is a timing chart showing a write operation when the burst chop is performed;

FIG. 7 is a more detailed timing chart for describing a latch margin of the command;

FIG. 8 is a circuit diagram of a command latch circuit in an example of separating a burst chop command into read-use and write-use at a previous stage of an AL counter;

FIG. 9 is a timing chart showing an operation of the circuit shown in FIG. 8;

FIG. 10 is a circuit diagram of a command control circuit according to the second embodiment of the present invention;

FIG. 11 is a timing chart showing a normal read operation of the command control circuit shown in FIG. 10;

FIG. 12 is a timing chart showing a read operation when the command control circuit shown in FIG. 11 performs the burst chop operation;

FIG. 13 is a circuit diagram of a command control circuit according to the third embodiment of the present invention;

FIG. 14 is a circuit diagram of a command control circuit according to the fourth embodiment of the present invention; and

FIG. 15 is a block diagram showing a data processing system using the DRAM that the present invention is applied.

### DETAILED DESCRIPTION OF THE EMBODIMENTS

Preferred embodiments of the present invention will now be explained in detail with reference to the drawings.

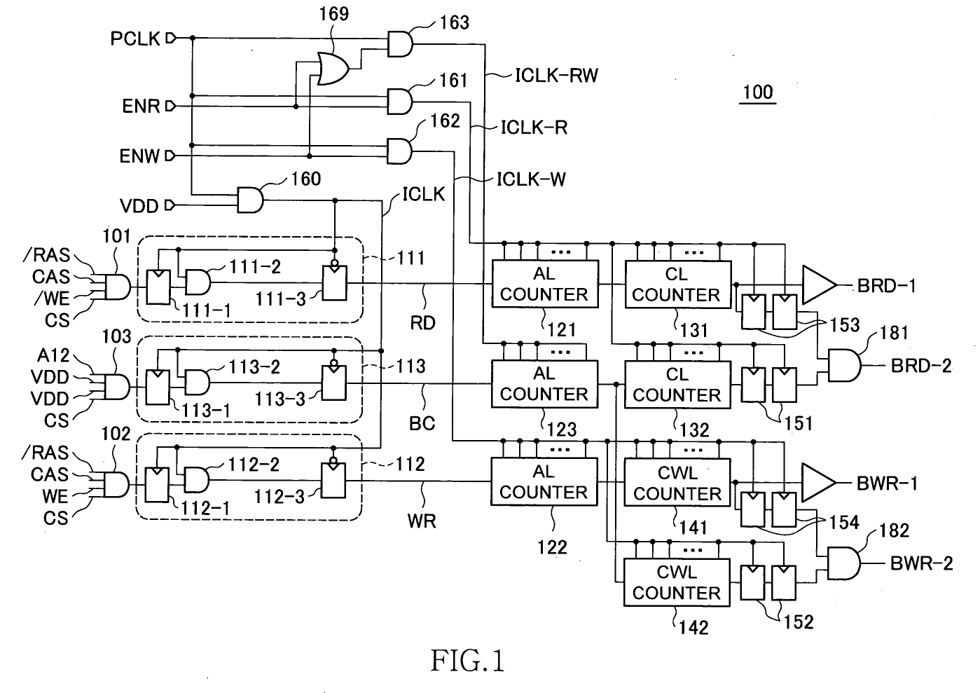

FIG. 1 is a circuit diagram of a command control circuit 100 according to a first embodiment of the present invention. It is possible to assemble the command control circuit 100 according to the embodiment into a semiconductor memory device of which prefetch number is 8 bits.

As shown in FIG. 1, the command control circuit 100 according to the present embodiment includes command decoders 101 to 103, command latch circuits 111 to 113, AL counters 121 to 123, CL counters 131 and 132, and CWL counters 141 and 142.

The command decoders 101 to 103 are circuits that decode a read command, a write command, and a burst chop command, respectively. The command decoders 101 to 103 are each configured of 4-input AND circuits, and when all of four signals are a high level, the command decoders 101 to 103 render corresponding commands active.

More specifically, the command decoder 101 renders a read command RD active when all of /RAS, which is an inverted signal of an RAS (row address strobe), a CAS (column address strobe), /WE, which is an inverted signal of a WE (write enable), and a CS (chip select) are a high level. The command decoder 102 renders a write command WR active when all of the /RAS, CAS, WE, and CS are a high level.

On the other hand, the command decoder 103 renders a burst chop command BC active when a signal A12 of a 12th address pin and the CS are a high level. Signals substantially inputted to the command decoder 103 are these two signals only. However, to be consistent with a circuit configuration with the other command decoders 101 and 102, the remaining two input terminals are fixedly inputted power supply potentials VDD.

The command latch circuits 111 to 113 latch the read command RD, the write command WR, and the burst chop command BC, in synchronization with an internal clock ICLK, respectively. The internal clock ICLK is generated by an internal-clock generation circuit 160. As shown in FIG. 1, the internal-clock generation circuit 160 is configured of a 2-input AND circuit to which an internal clock PCLK and a power supply potential VDD are supplied. Accordingly, waveforms of the internal clock ICLK and the internal clock PCLK are substantially consistent, and to be consistent with timing with a read clock or a write clock described later, these clocks are passed by way of the internal-clock generation circuit 160.

The command latch circuits 111 to 113 have the same circuit configuration each other. More specifically, the command latch circuits 111 to 113 are configured of latch circuits 111-1 to 113-1, AND circuits 111-2 to 113-2, and latch circuits 111-3 to 113-3.

The latch circuits 111-1 to 113-1 latch a corresponding command in synchronization with a rising edge of the internal clock ICLK and output the fetched command in synchronization with a falling edge of the internal clock ICLK. Thereby, a count of one clock is performed by the latch circuits 111-1 to 113-1. Outputs of the latch circuits 111-1 to 113-1 are supplied to input terminals, on one side, of AND circuits 111-2 to 113-2. Input terminals, on the other side, of the AND circuits 111-2 to 113-2 are supplied the internal clock ICLK. Outputs of the AND circuits 111-2 to 113-2 are supplied to the latch circuits 111-3 to 113-3. The latch circuits 111-3 to 113-3 latch a corresponding command in synchronization with the falling edge of the internal clock ICLK and output the command. Thereby, a count of 0.5 clocks is performed by the latch circuits 111-3 to 113-3.

The AL counters 121 to 123 count additive latencies of the read command RD, the write command WR, and the burst chop command BC, respectively. That is, the AL counter 121 functions as a read AL counter, the AL counter 122 functions as a write AL counter, and the AL counter 123 functions as a burst chop command AL counter.

The AL counter 121 or read AL counter counts the read command RD in synchronization with a read clock ICLK-R. The read clock ICLK-R is generated by a read-clock generation circuit 161. As shown in FIG. 1, the read-clock generation circuit 161 is configured of a 2-input AND circuit to which the internal clock PCLK and a read enable signal ENR are supplied. Thereby, the read clock ICLK-R performs clocking at the time of reading only.

The AL counter 122 or write AL counter counts the write command WR in synchronization with a write clock ICLK-W. The write clock ICLK-W is generated by a write-clock generation circuit 162. As shown in FIG. 1, the write-clock generation circuit 162 is configured of a 2-input AND circuit to which the internal clock PCLK and a write enable signal ENW are supplied. Thereby, the write clock ICLK-W performs clocking at the time of writing only.

The AL counter 123 or burst chop AL counter counts the burst chop command BC in synchronization with a read/write clock ICLK-RW. The read/write clock ICLK-RW is generated by a read/write-clock generation circuit 163. As shown in FIG. 1, the read/write-clock generation circuit 163 is configured of a 2-input AND circuit to which the internal clock PCLK and output of an OR circuit 169 are supplied. An input terminal of the OR circuit 169 herein is supplied the read enable signal ENR and the write enable signal ENW. Thereby, the read/write clock ICLK-RW performs clocking at the time of reading and writing.

The CL counters 131 and 132 count CAS latencies of the read command RD and the burst chop command BC at the time of reading, respectively. Both the CL counters 131 and 132 operate in synchronization with the read clock ICLK-R, and each counter counts the read command RD and the burst chop command BC.

At the subsequent stage of the CL counters 131 and 132, adjustment counters 153 and 151 that control timing of the burst chop in synchronization with the read clock ICLK-R are respectively added. In the present embodiment, the adjustment counters 153 and 151 are configured of two latch circuits dependently connected, and the both counters operate in synchronization with the read clock ICLK-R. In the DDR synchronous DRAM, input and output of data are performed in synchronization with both the rising edge and the falling edge of the clock, and thus, the adjustment counters 153 and 151 configured of the two latch circuits serve to function delaying outputs of the CL counters 131 and 132 by 4 data.

As shown in FIG. 1, the output of the CL counter 131 is used as a read burst control signal BRD-1. On the other hand, output, which passes through the adjustment counters 153, of the CL counter 131, and output, which passes through the adjustment counters 151, of the CL counter 132, are supplied to an AND circuit 181. Output of the AND circuit 181 is used as a read burst control signal BRD-2.

CWL counters 141 and 142 count CAS write latencies of the write command WR and the burst chop command BC at the time of writing, respectively. Both the CWL counters 141 and 142 operate in synchronization with the write clock ICLK-W, and each counter counts the write command RD and the burst chop command BC.

At the subsequent stage of the CWL counters 141 and 142, adjustment counters 154 and 152 that control timing of the burst chop in synchronization with the write clock ICLK-W are respectively added. The adjustment counters 154 and 152 have the same circuit configuration as the adjustment counters 153 and 151. Thereby, the adjustment counters 154 and 152 serve to function delaying outputs of the CWL counters 141 and 142 by 4 data.

Output of the CWL counter 141 is used as a write burst control signal BWR-1. On the other hand, output, which passes through the adjustment counters 154, of the CWL counter 141, and output, which passes through the adjustment counters 152, of the CWL counter 142, are supplied to an AND circuit 182. Output of the AND circuit 182 is used as a write burst control signal BWR-2.

Thus, the circuit configuration of the command control circuit 100 according to the present embodiment is described.

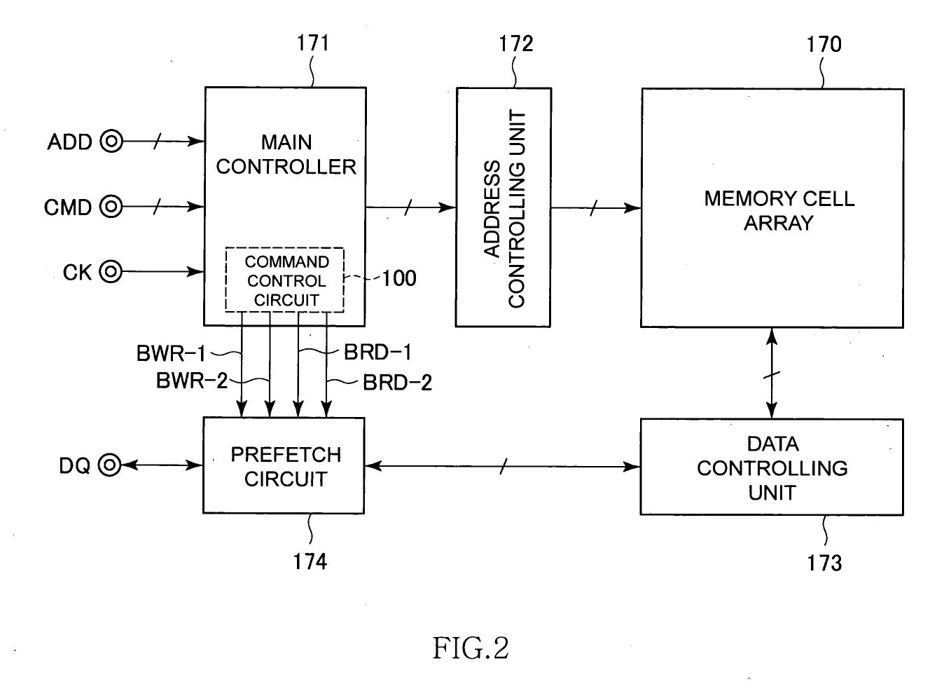

The command control circuit 100 having such a configuration is assembled as a circuit that configures one portion of a main controller 171 of a semiconductor memory device shown in FIG. 2.

The semiconductor memory device shown in FIG. 2 is a DRAM, and includes a memory cell array 170, the main controller 171 that controls an operation of the entire device in receipt of an address ADD, a command CMD, and an external clock CK, an address controlling unit 172 that accesses the memory cell array 170 under the control of the main controller 171, a data controlling unit 173 that inputs and outputs data to and from the memory cell array 170, and a prefetch circuit 174 arranged between the data controlling unit 173 and a data input/output pin DQ.

As shown in FIG. 2, the burst control signals BRD-1, BRD-2, BWR-1, and BWR-2, which are the outputs of the command control circuit 100, are supplied at least to the prefetch circuit 174, and thereby, a burst operation is controlled.

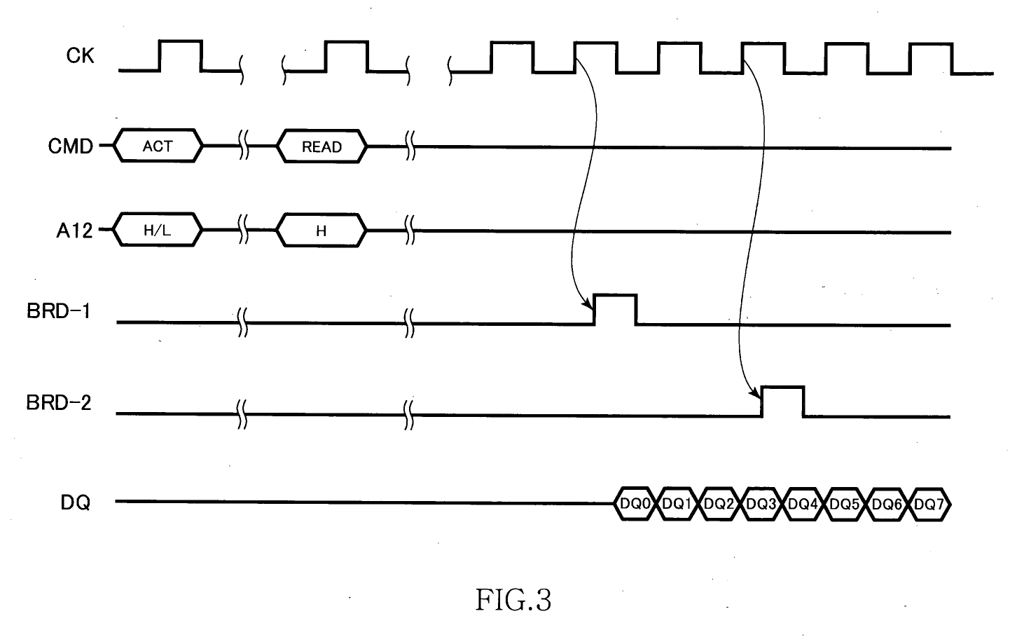

FIG. 3 to FIG. 6 are timing charts showing the operation of the command control circuit 100 according to the present embodiment.

FIG. 3 is a timing chart showing a normal read operation. The normal read operation herein indicates a case where a burst read is performed without performing a burst chop operation.

As shown in FIG. 3, when the normal read operation is performed, in synchronization with the external clock CK, an ACT command and a read command READ are supplied in this order, and a level of a 12th address pin A12 at the time of supplying the read command READ is set to a high level. At the time of inputting the ACT command, a row address is supplied to the address pin, and at the time of inputting the read command READ, a column address is supplied to the address pin. The 12th address pin A12 at the time of supplying the read command READ is not used for inputting the column address.

As a result of such command input, the outputs of the command decoders 101 and 103 become a high level. Thus, both the read command RD and the burst chop command BC are rendered active. Alternatively, at the time of the reading operation, the read enable signal ENR is rendered active, and thus, the read clock ICLK-R performs clocking.

Thereby, in the read command RD and the burst chop command BC, the additive latencies are counted by the AL counters 121 and 123, respectively, and further, the CAS latencies are counted by the CL counters 131 and 132. Thus, when the count by the CL counter 131 is ended, the read burst control signal BRD-1 is rendered active.

On the other hand, at the subsequent stage of the CL counter 132, the adjustment counters 151 are arranged. Thus, when the count by the CL counter 132 is ended, the read burst control signal BRD-2 is rendered active with a delay of two clocks from the read burst control signal BRD-1.

The read burst control signal BRD-1 permits outputting of upper 4 bits of 8 bits of prefetched read data. On the other hand, the read burst control signal BRD-2 permits outputting of lower 4 bits of 8 bits of prefetched read data. In the normal read operation shown in FIG. 3, after the read burst control signal BRD-1 is rendered active, the read burst control signal BRD-2 is rendered active with a delay of two clocks. Thus, prefetched 8-bit read data is continuously outputted as shown in FIG. 3.

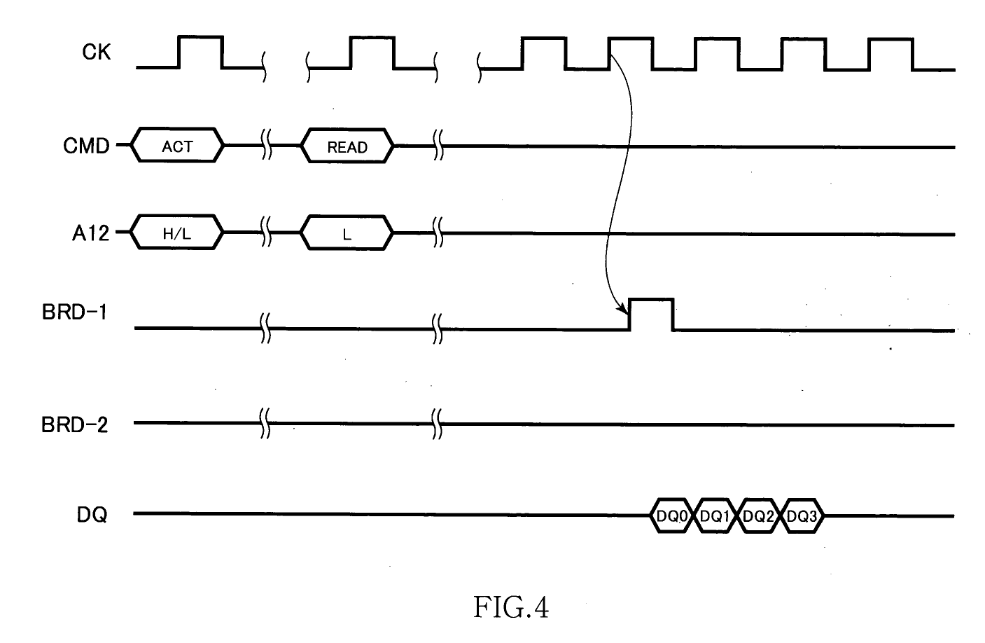

FIG. 4 is a timing chart showing a read operation when the burst chop is performed.

As shown in FIG. 4, when the burst chop is performed in the read operation, the level of the 12th address pin A12 at the time of supplying the read command READ is set to a low level. As a result, inside of the command control circuit 100, the output of the command decoder 101 becomes a high level. Thus, the read command RD only is rendered active, and the burst chop command BC is not rendered active.

Thereby, the read burst control signal BRD-1 only is rendered active. As a result, only the upper 4 bits of the 8 bits of prefetched read data are outputted, and the lower 4 bits are not outputted. That is, a burst length=4 is achieved.

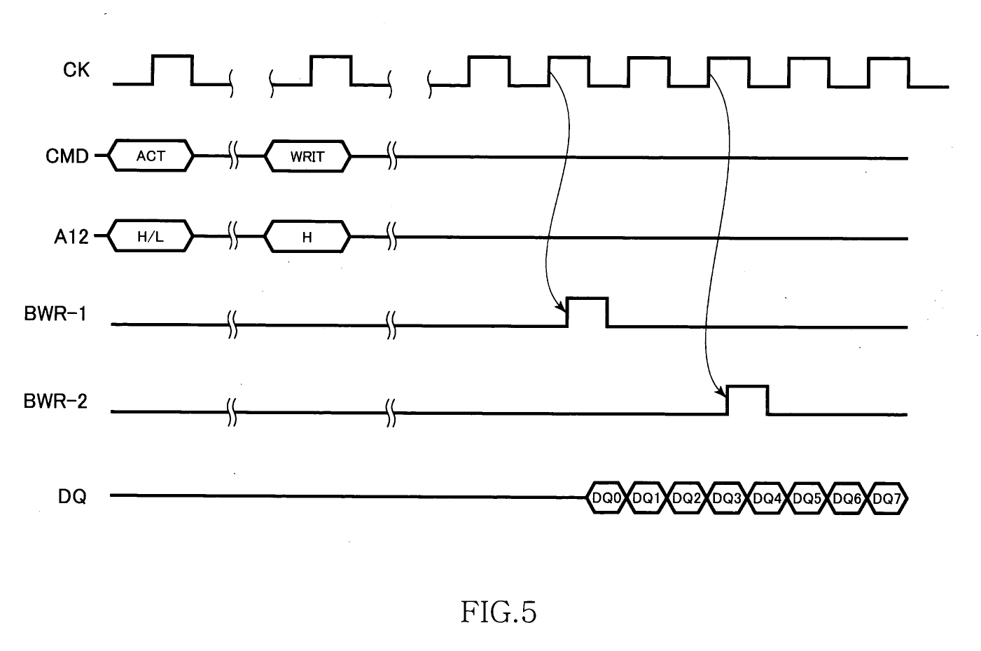

FIG. 5 is a timing chart showing a normal write operation. The normal write operation herein indicates a case where a burst write is performed without performing the burst chop operation.

As shown in FIG. 5, when the normal write operation is performed, in synchronization with the external clock CK, the ACT command and a write command WRIT are supplied in this order, and the level of the 12th address pin A12 at the time of supplying the write command WRIT is set to a high level. Thereby, the outputs of the command decoders 102 and 103 become a high level. As a result, both the write command WR and the burst chop command BC are rendered active. Alternatively, at the time of the write operation, the write enable signal ENW is rendered active. Thus, the write clock ICLK-W performs clocking.

Thereby, in the write command WR and the burst chop command BC, the additive latencies are counted by the AL counters 122 and 123, respectively, and further, the CAS write latencies are respectively counted by the CWL counters 141 and 142. As a result, when the count by the CWL counter 141 is ended, the write burst control signal BWR-1 is rendered active.

On the other hand, at the subsequent stage of the CWL counter 142, the adjustment counters 152 are arranged. Thus, when the count by the CWL counter 142 is ended, the write burst control signal BWR-2 is rendered active with a delay of 2 clocks from the write burst control signal BWR-1.

The write burst control signal BWR-1 permits inputting of write data to be prefetched in a portion of upper 4 bits of the prefetch circuit. On the other hand, the write burst control signal BWR-2 permits inputting of the write data to be prefetched in a portion of lower 4 bits of the prefetch circuit. In the normal write operation shown in FIG. 5, after the write burst control signal BWR-1 is rendered active, the write burst control signal BWR-2 is rendered active with a delay of 2 clocks. Thus, it becomes possible to burst-input the 8-bit write data.

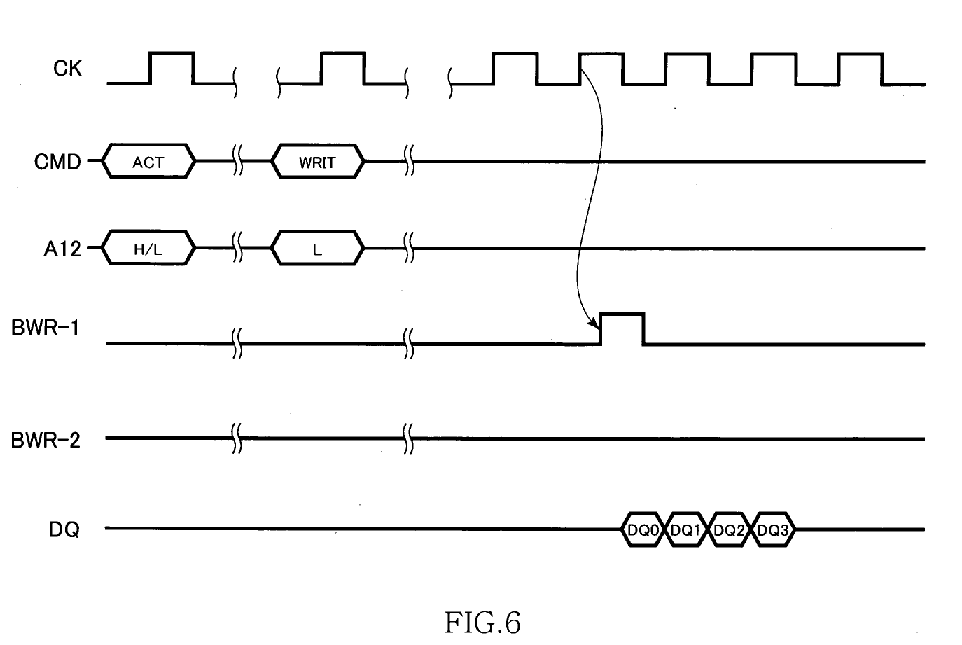

FIG. 6 is a timing chart showing a write operation when the burst chop is performed.

As shown in FIG. 6, when the burst chop is performed in the write operation, the level of the 12th address pin A12 at the time of supplying the write command WRIT is set to a low level. Thereby, the output of the command decoder 102 becomes a high level. As a result, inside of the command control circuit 100, the write command WR only is rendered active, and the burst chop command BC is not rendered active.

As a result, the write burst control signal BWR-1 only is rendered active. Thus, the write data to be burst-inputted are limited to its upper 4 bits. That is, the burst length=4 is achieved.

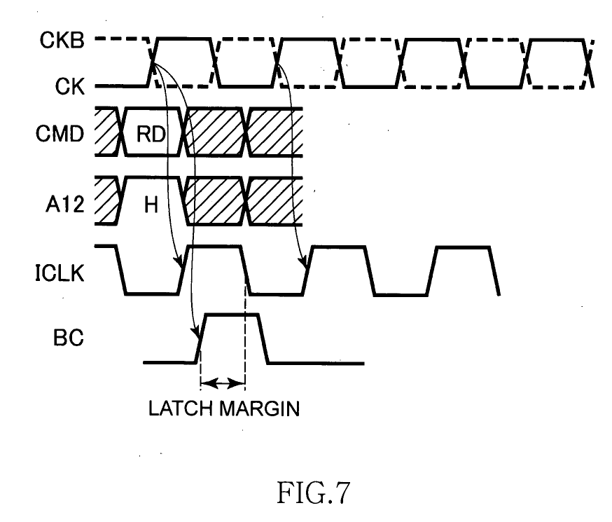

FIG. 7 is a more detailed timing chart for describing a latch margin of the command. FIG. 7 shows, as an example, an operation of the command latch circuit 113 at the time of a normal read. The same is true for an operation at the time of writing and an operation of the burst chop. Further, the same is true for operations of the other command latch circuits 111 and 112.

As described in FIG. 1, while the first-stage latch circuit 113-1 included in the command latch circuit 113 latches the command in response to the rising edge of the internal clock ICLK, the second-stage latch circuit 113-3 included in the command latch circuit 113 latches the command in response to the falling edge of the internal clock ICLK. Thus, a period during which the output of the AND circuit 113-2 changes in response to the rising edge of the internal clock ICLK, and thereafter, the internal clock ICLK falls results in a latch margin of the latch circuit 113-3. In the present embodiment, between the latch circuit 113-1 and the latch circuit 113-3, the AND circuit 113-2 only exists. Thus, it becomes possible to maintain a sufficient latch margin.

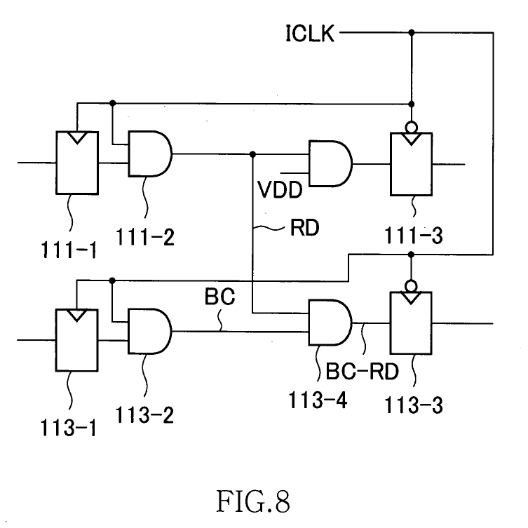

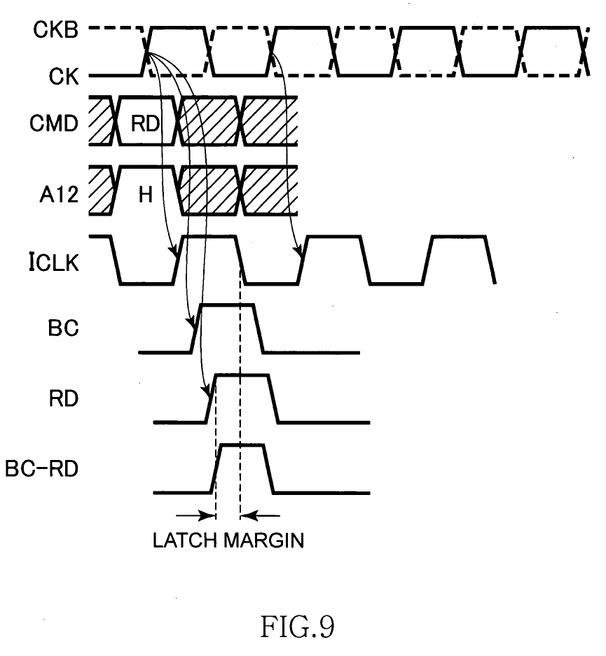

On the contrary, as shown in FIG. 8, for example, when it is attempted to separate the burst chop command BC into read-use and write-use at the previous stage of the AL counter, between the latch circuit 113-1 and the latch circuit 113-3, one more stage of the AND circuit 113-4 to which the read command (or the write command) is inputted is necessary, in addition to the AND circuit 113-2. In this case, as shown in FIG. 9, the latch margin of the latch circuit 113-3 is defined by a period during which the read (or write) burst chop command BC-RD is established, and thereafter, the internal clock ICLK falls, and as a result, the latch margin is very small as compared to the present embodiment.

As described above, according to the present embodiment, the burst chop AL counter is used commonly for the read and the write. Thus, it is not necessary to arrange two AL counters that count the burst chop command. Accordingly, it becomes possible to inhibit the circuit scale of the command control circuit.

Further, it is not necessary to separate the burst chop command BC into the read-use and the write-use at the previous stage of the burst chop AL counter 123. Thus, it becomes possible to inhibit the number of stages of the command latch circuits 111 to 113. Thereby, it becomes also possible to sufficiently maintain the latch margin of the command latch circuits 111 to 113.

A second embodiment of the present invention is explained next.

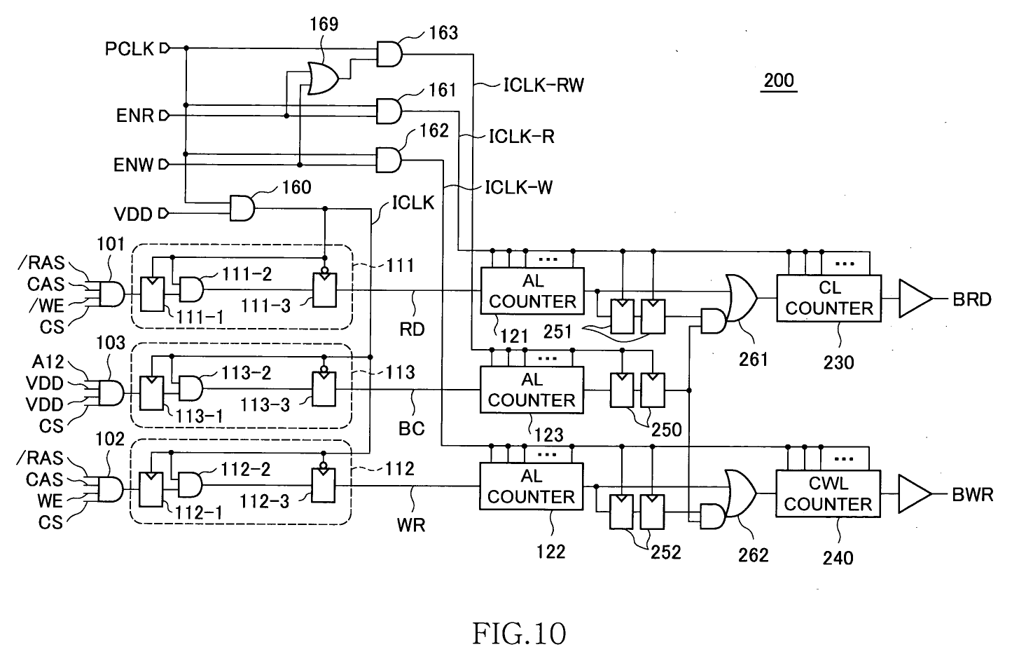

FIG. 10 is a circuit diagram of a command control circuit 200 according to the second embodiment.

In the command control circuit 200 according to the present embodiment, two CL counters are integrated into one CL counter 230 and two CWL counters are integrated into one CWL counter 240. As a result, adjustment counters 250 to 252 that control timing of the burst chop are arranged at the subsequent stage of the AL counters 123, 121, and 122. Other points are basically identical to those of the command control circuit 100 of the first embodiment. Thus, like parts are designated with like reference numerals, and duplicated explanations are omitted.

As shown in FIG. 10, the burst chop command BC, which is output of the adjustment counters 250, is supplied commonly to AND-OR circuits 261 and 262.

The AND-OR circuit 261 receives the burst chop command BC, the read command RD, which is the output of the AL counter 121, and output of the adjustment counters 251. Output of the AND-OR circuit 261 is supplied to the CL counter 230. Thereby, the CL counter 230 results in counting both the read command RD and the burst chop command BC.

On the other hand, the AND-OR circuit 262 receives the burst chop command BC, the write command WR, which is the output of the AL counter 122, and output of the adjustment counters 252. Output of the AND-OR circuit 262 is supplied to the CWL counter 240. Thereby, the CWL counter 240 results in counting both the write command WR and the burst chop command BC.

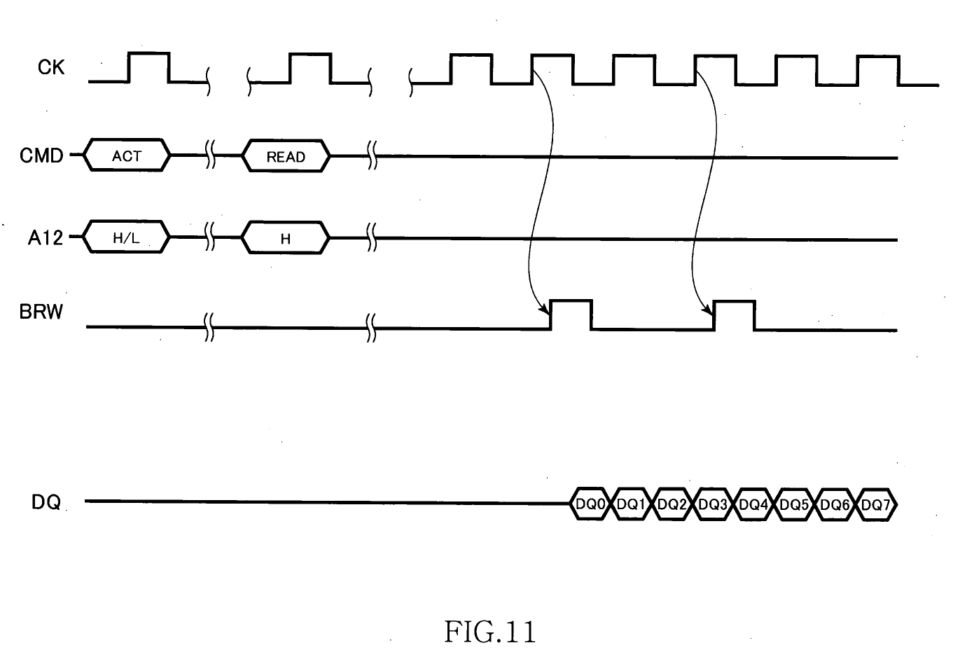

FIG. 11 is a timing chart showing a normal read operation of the command control circuit 200 according to the present embodiment.

As described above, when the normal read operation is operated, both the read command RD and the burst chop command BC are rendered active. Thus, the CL counter 230 is sequentially supplied these commands. A timing difference between the read command RD and the burst chop command BC is determined by a count number of the adjustment counters 250, and in the present embodiment, a difference of 2 clocks occurs.

As a result, a read burst control signal BRD is rendered active once, and thereafter, rendered active once again after 2 clocks. The first active signal permits outputting of upper 4 bits of 8 bits of prefetched read data. The second active signal permits outputting of lower 4 bits of 8 bits of prefetched read data. As a result, prefetched 8-bit read data is continuously outputted as shown in FIG. 11.

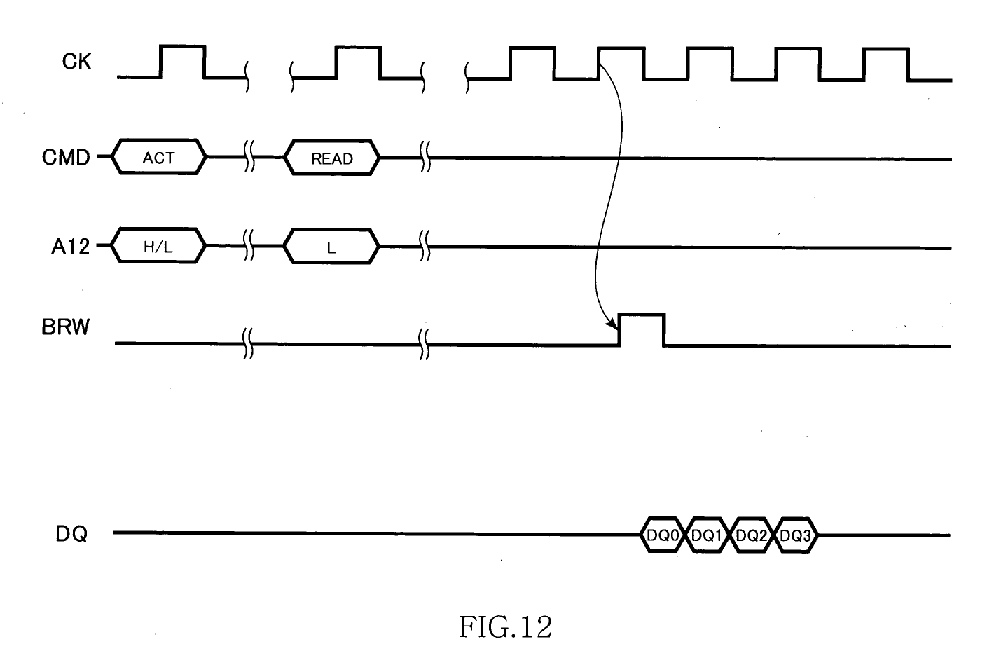

FIG. 12 is a timing chart showing a read operation when the command control circuit 200 according to the present embodiment performs the burst chop.

When the burst chop is performed in the read operation, the read command RD only is rendered active, and the burst chop command BC is not rendered active. Thus, the read burst control signal BRD is rendered active only once, and thus, only the upper 4 bits of the 8 bits of prefetched read data are outputted, and the lower 4 bits are not outputted. That is, the burst length=4 is achieved.

The same is true for the write operation. In the normal operation, the write burst control signal BWR is rendered active twice, and when the burst chop is performed, the write burst control signal BWR is rendered active only once.

Thus, according to the present embodiment, the CL counter 230 and the CWL counter 240 are integrated into one unit, respectively, and accordingly, it is possible to further downsize the circuit scale. Further, the operated counter number is rendered small, and thus, it is also possible to reduce power consumption.

A third embodiment of the present invention is explained next.

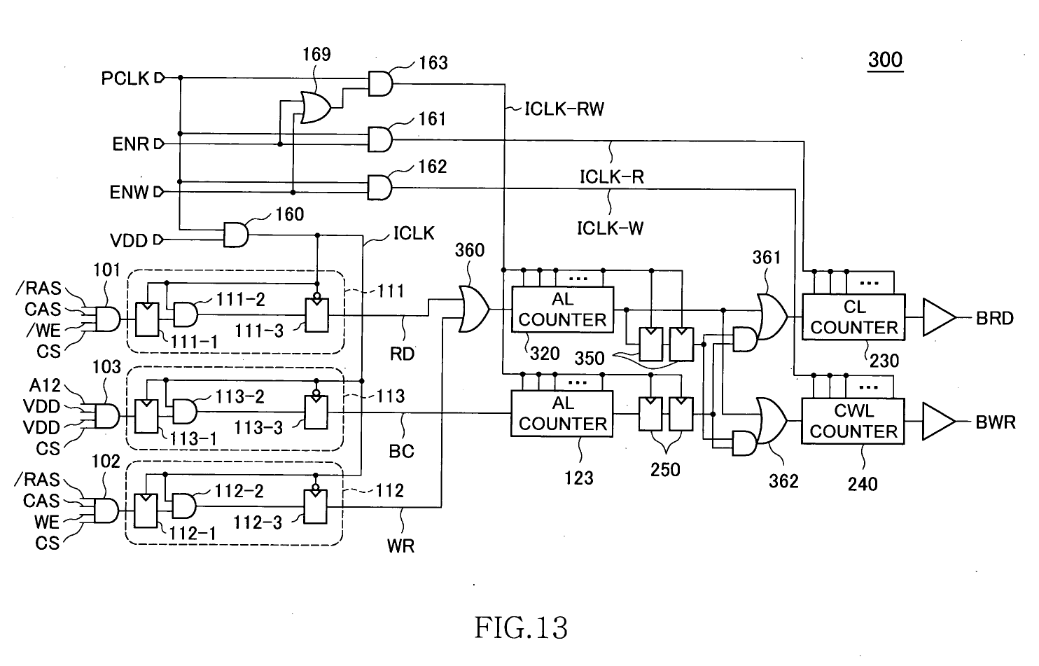

FIG. 13 is a circuit diagram of a command control circuit 300 according to the third embodiment.

In the command control circuit 300 according to the present embodiment, the read AL counter and the write AL counter are integrated into one AL counter (read/write combined AL counter) 320. As a result, regarding the adjustment counter, common adjustment counters 350 are used for the read and the write. Other points are basically identical to those of the command control circuit 200 of the second embodiment. Thus, like parts are designated by like reference numerals, and duplicated explanations are omitted.

As shown in FIG. 13, the read command RD, which is the output of the command latch circuit 111, and the write command WR, which is the output of the command latch circuit 112, are inputted to an OR circuit 360. Output of the OR circuit 360 is supplied to the read/write combined AL counter 320. Thereby, the read/write combined AL counter 320 results in counting both the read command RD and the write command WR. The read/write combined AL counter 320 operates in synchronization with the read/write clock ICLK-RW, similar to the AL counter 123 that counts the burst chop command BC.

Output of the read/write combined AL counter 320 is supplied commonly to AND-OR circuits 361 and 362. Output of the adjustment counters 250 is also supplied commonly to the AND-OR circuits 361 and 362. Output of adjustment counters 350 is also supplied commonly to the AND-OR circuits 361 and 362. Thereby, both the outputs of the AL counters 123 and 320 are supplied to the CL counter 230 and the CWL counter 240.

However, the CL counter 230 operates when the read clock ICLK-R is clocking. Thus, it is only the read command RD and the burst chop command BC at the time of reading that are counted by the CL counter 230. Likewise, the CWL counter 240 operates when the write clock ICLK-W is clocking. Thus, it is only the write command WR and the burst chop command BC at the time of writing that are counted by the CWL counter 240.

Thereby, the command control circuit 300 according to the present embodiment becomes capable of operating similarly to the command control circuit 200. Further, in the command control circuit 300 according to the embodiment, the read AL counter and the write AL counter are integrated into one read/write AL combined counter 320. Thus, it becomes possible to further downsize the circuit scale.

A fourth embodiment of the present invention is explained next.

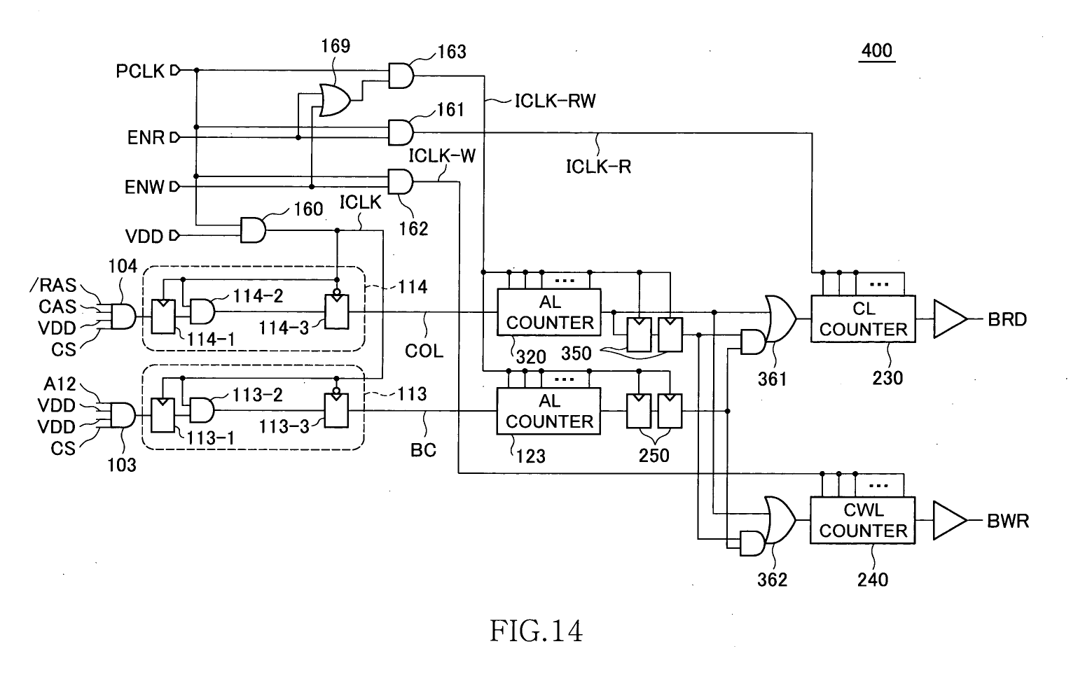

FIG. 14 is a circuit diagram of a command control circuit 400 according to the fourth embodiment.

In the command control circuit 400 according to the present embodiment, the read command decoder 101 and the command latch circuit 111, and the write command decoder 102 and the command latch circuit 112 are integrated into a common command decoder 104 and command latch circuit 114, respectively. As a result, the OR circuit 360 is eliminated. Other points are basically identical to those of the command control circuit 300 of the third embodiment. Thus, like parts are designated with like reference numerals, and duplicated explanations are omitted.

As shown in FIG. 14, the command decoder 104 is supplied the /RAS, CAS, VDD, and CS. Thereby, when all become a high level, a column command COL is rendered active. The column command COL does not include the WE signal. Accordingly, it is not possible from the column command COL to determine whether a requested operation is the read or the write.

However, as described above, the read clock ICLK-R performs the clocking at the time of reading only, and the write clock ICLK-W performs the clocking at the time of writing only. Thus, it becomes possible to perform completely the same as the command control circuit 300 shown in FIG. 13.

The present invention can preferably apply to the semiconductor memory device, especially a DRAM.

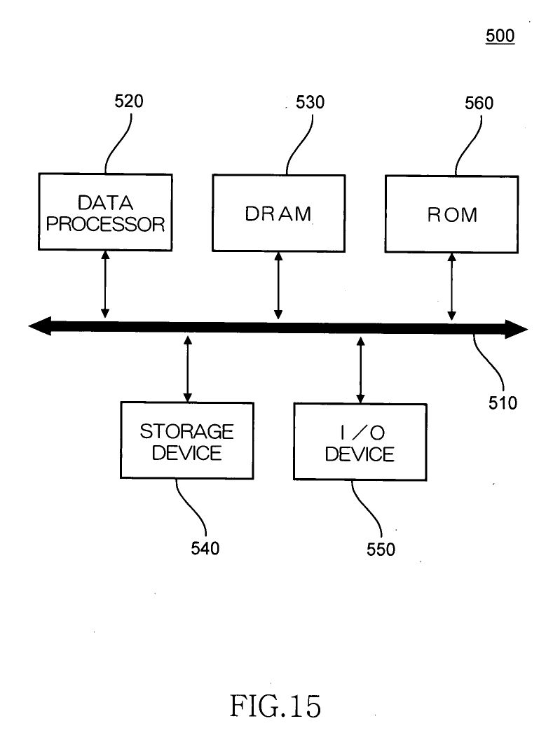

FIG. 15 is a block diagram showing a data processing system using the DRAM that the present invention is applied.

The data processing system 500 shown in FIG. 15 includes a data processor 520 and a DRAM 530 that the present invention is applied are connected to each other via a system bus 510. The data processor 520 can be selected from at least a microprocessor (MPU) and a digital signal processor (DSP). In FIG. 15, although the data processor 520 and the DRAM 530 are connected via the system bus 510 in order to simplify the diagram, they can be connected via not the system bus 510 but a local bus.

Further, in FIG. 15, although only one set of system bus 510 is employed in the data processing system 500 in order to simplify the diagram, a serial bus or a parallel bus connected to the system bus 510 via connectors can be provided. As shown in FIG. 15, a storage device 540, an I/O device 550, and a ROM 560 are connected to the system bus 510. However, they are not essential element for the data processing system 500.

The storage device 540 can be selected from at least a hard disk drive, an optical disk drive, and flash memory device. The I/O device 550 can be selected from a display device such as a liquid crystal display (LCD) and an input device such as a key board or a mouse. The I/O device 550 can consists of either input or output device. Further, although each one element is provided as shown in FIG. 15, two or more same elements can be provided in the data processing system.

The present invention is in no way limited to the aforementioned embodiments, but rather various modifications are possible within the scope of the invention as recited in the claims, and naturally these modifications are included within the scope of the invention.

For example, in the above embodiment, the description is given of a case where the prefetch number is 8 bits and the burst length at the time of the burst chop is 4 bits. However, the present invention is not limited thereto. The prefetch number and the burst length at the time of the burst chop are arbitrary. That is, when the prefetch number is m bits (where m is an integer of 2 or more), it is sufficient that the burst chop command indicates whether to permit the burst operation subsequent to n bits (where n is an integer of less than m).

Alternatively, it is not always essential that the burst length at the time of the burst chop be half the prefetch number, and it can also be configured such that two or more types of burst chops can be possible for the prefetch number. For example, it can be configured such that the prefetch number is 32 bits, and the burst length at the time of the burst chop is selectable in two stages, that is, 8 bits and 16 bits.

Alternatively, positions of the adjustment counters are not limited to those in the embodiments described above, and these counters can be arranged in any position on a path where the burst chop command BC is transmitted. Accordingly, the adjustment counters can be arranged at the previous stage of the AL counter 123, for example.

According to the present invention, a burst chop AL counter operates in synchronization with both a read clock and a write clock. This eliminates a need of separately arranging an AL counter that counts the burst chop command at the time of reading and an AL counter that counts the burst chop command at the time of writing. As a result, it becomes possible to inhibit an increase in circuit scale of a command control circuit.

The burst chop AL counter is used commonly for write and read. Thus, it becomes possible to eliminate the need of separating the burst chop command into read-use and write-use at the previous stage of the burst chop AL counter. This makes it also possible to sufficiently maintain a latch margin in the command latch circuit.

What is claimed is:

1. A command control circuit comprising:
a read-clock generation circuit that generates a read clock during a read operation;
a write-clock generation circuit that generates a write clock during a write operation; and
a burst chop AL counter that counts an additive latency of a burst chop command in synchronization with both the read clock and the write clock.

2. The command control circuit as claimed in claim 1, wherein the burst chop command is generated by a predetermined signal combination including a signal supplied via a predetermined address terminal.

3. The command control circuit as claimed in claim 1, further comprising:
a read AL counter that counts an additive latency of a read command; and
a write AL counter that counts an additive latency of a write command, wherein
the read AL counter counts the read command in synchronization with the read clock, and the write AL counter counts the write command in synchronization with the write clock.

4. The command control circuit as claimed in claim 3, further comprising:
a first CL counter, arranged at a subsequent stage of the read AL counter, that counts a CAS latency of the read command;
a first CWL counter, arranged at a subsequent stage of the write AL counter, that counts a CAS write latency of the write command;
a second CL counter, arranged at a subsequent stage of the burst chop AL counter, that counts a CAS latency of the burst chop command; and
a second CWL counter, arranged at a subsequent stage of the burst chop AL counter, that counts a CAS write latency of the burst chop command, wherein
the first and second CL counters respectively count the read command and the burst chop command in synchronization with the read clock, and
the first and second CWL counters respectively count the write command and the burst chop command in synchronization with the write clock.

5. The command control circuit as claimed in claim 4, further comprising:
a first adjustment counter, arranged at a previous stage or a subsequent stage of the second CL counter, that controls timing of a burst chop in synchronization with the read clock; and
a second adjustment counter, arranged at a previous stage or a subsequent stage of the second CWL counter, that controls timing of the burst chop in synchronization with the write clock, wherein
a count number of the first adjustment counter and a count number of the second adjustment counter are equal.

6. The command control circuit as claimed in claim 3, further comprising:
a CL counter, arranged at a subsequent stage of the read AL counter, that counts a CAS latency of the read command; and
a CWL counter, arranged at a subsequent stage of the write AL counter, that counts a CAS write latency of the write command, wherein
output of the burst chop AL counter is supplied commonly to the CL counter and the CWL counter.

7. The command control circuit as claimed in claim 6, further comprising an adjustment counter, arranged at a previous stage or a subsequent stage of the burst chop AL counter, that controls timing of a burst chop in synchronization with both the read clock and the write clock.

8. The command control circuit as claimed in claim 1, further comprising a read/write combined AL counter that counts additive latencies of a read command and a write command, wherein
the read/write combined AL counter counts the read command and the write command in synchronization with both the read clock and the write clock.

9. The command control circuit as claimed in claim 1, wherein when a prefetch number is m bits (where m is an integer of 2 or more), the burst chop command is a command indicating whether to permit a burst operation subsequent to n bits (where n is an integer of less than m).

10. The command control circuit as claimed in claim 9, wherein the m bits are two times the n bits.

11. A semiconductor memory device comprising a memory cell array and a command control circuit, wherein the command control circuit includes:
a read-clock generation circuit that generates a read clock during a read operation;
a write-clock generation circuit that generates a write clock during a write operation; and
a burst chop AL counter that counts an additive latency of a burst chop command in synchronization with both the read clock and the write clock.

12. A data processing system comprising a data processor and a semiconductor memory device,
wherein the semiconductor memory device includes a memory cell array and a command control circuit,
wherein the command control circuit having:
a read-clock generation circuit that generates a read clock during a read operation;
a write-clock generation circuit that generates a write clock during a write operation; and
a burst chop AL counter that counts an additive latency of a burst chop command in synchronization with both the read clock and the write clock.
